(19) United States
(12) Patent Application Publication
(10) Pub. No.: US 2026/0182040 A1
(43) Pub. Date: Jun. 25, 2026

(54) MULTI-LAYER THREE-DIMENSIONAL CIRCUIT STRUCTURES WITH IMPROVED THERMAL CONDUCTIVITY

(71) Applicant: NVIDIA Corp., Santa Clara, CA (US)

(72) Inventors: John Michael Wilson, Wake Forest, NC (US); Walker Joseph Turner, Jacksonville Beach, FL (US)

(73) Assignee: NVIDIA Corp., Santa Clara, CA (US)

(21) Appl. No.: 19/431,109

(22) Filed: Dec. 23, 2025

Related U.S. Application Data
(60) Provisional application No. 63/738,347, filed on Dec. 23, 2024.

(51) Int. Cl. H10D 88/00; H10B 80/00; H10W 20/41

(52) U.S. Cl. CPC H10D 88/00; H10B 80/00; H10W 20/427

(57) ABSTRACT

Mechanisms to improve the thermal conductivity of three-dimensional integrated circuit (3DIC) structures by thinning the metal and dielectric layers in comparison to the dimensions of these layers in conventional 3DIC structures, resulting in a commensurate thinning of the oxide layers between active layers and metal layers, and a reduction in the number of metal and oxide layers utilized compared to conventional 3DIC structures.

### CROSS REFERENCE TO RELATED APPLICATIONS

This application claims priority and benefit under 35 U.S.C. 119 (e) to U.S. Application Ser. No. 63/738,347, “Methods to thermally optimized metal and dielectric layers for multi-layer 3DICs”, filed on Dec. 23, 2024, the contents of which are incorporated herein by reference in their entirety.

### STATEMENT OF GOVERNMENT INTEREST

This invention was made with US Government support under SNL Prime Contract DE-NA0003525 (Advanced Memory Technology) awarded by the Department of Energy (DOE). The US Government has certain rights in this invention.

### BACKGROUND

The construction and operation of three-dimensional integrated circuits (3DICs) is challenged by problems of heat removal and power delivery. The problem of heat removal is exacerbated by conditions in which multiple circuit dice are arranged in a two-dimensional (2D) plane and stacked on top of one other to create a 3D structure. The power-per-area density and hence the heat flux density of such circuit structures may quickly multiply as more layers are added.

The thermal impedance of multi-layer circuit structures tends to be higher than for an equivalent 2D structure because each layer added to the 3D stack increases the thermal impedance. This is due to each die comprising layers of metal and silicon dioxide adjacent to the active layer(s) of silicon.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1A and FIG. 1B depict exemplary 3DIC structures.

FIG. 2A-FIG. 2E depict exemplary 3DIC layer configurations.

FIG. 3A depicts a conventional 3DIC structure.

FIG. 3B depicts a thermal improvement to a 3DIC structure in one embodiment.

FIG. 4A depicts a conventional 3DIC structure.

FIG. 4B depicts a 3DIC embodiment comprising normalization of wire thickness across metal layers and reduction of oxide thickness between power/ground layers by 50%.

FIG. 4C depicts a 3DIC embodiment utilizing a smaller number of higher resolution metal layers.

FIG. 5A-FIG. 5D depict a progression that reduces dielectric layers in a 3DIC structure and thereby improves thermal conductivity.

FIG. 6A-FIG. 6C depict configurations of through-silicon via stripes in a metal layer.

### DETAILED DESCRIPTION

Materials commonly utilized in semiconductor fabrication are metal (e.g., copper), silicon, and dielectric material (e.g., silicon dioxide). Copper and other metals are very good conductors of heat. Copper for example may comprise a thermal conductivity of around 400 W-mK. Silicon may comprise a thermal conductivity of around 100-140 W-mK. Silicon dioxide, or oxide for short, provides an electrical insulating layer between metal layers in a 3DIC and the active (silicon) layers.

Oxide does not conduct heat well and may comprise a thermal conductivity of around 1.2 W-mK for bulk material and 0.2-to-0.3 W-mK for the porous oxide used in modern integrated circuit fabrication. Compared to copper or silicon, oxide acts like a thermal insulator.

Disclosed herein are mechanisms to thin the metal and dielectric layers of 3DIC structures in comparison to the conventional dimensions of these layers, thereby improving thermal conductivity of the 3DIC structure. A commensurate thinning of the oxide layers between active layers and metal may follow, further improving the thermal conductivity. In addition to thinning the metal and oxide layers, the disclosed mechanisms also enable a reduction in the number of metal and oxide layers utilized compared to conventional 3DIC structures.

The use of thinner metal layers enables higher planar metal route density which in turn enables the use of fewer layers without increasing the overall (3D) metal routing density. Thinner metal layers comprise higher thermal and electrical resistance than thicker ones and therefore lower the signaling bandwidth within those layers. However, the use of thinner metal layers enables the configuration of via stripes to convert longer laterally-routed signal wires into shorter vertical wires (vias) by bringing transistors, and logic blocks, into closer proximity. While there will still be lateral signal routing in structures with thinner metal layers, the maximum lateral and/or overall wire lengths may be shortened.

The bandwidth capacity of in-chip wires is inversely proportional to their length squared. Therefore, shorter wires may be constructed using wires with a smaller cross-sectional area (thinner and narrower) with equivalent bandwidth of the longer, thicker wires.

$$B {W}_{w i r e} = \frac{1}{2 π \cdot {R}_{w i r e} {C}_{w i r e}}$$

As the density of logic increases, a greater number of metal layers may be utilized to provide power and signals to the increased number of circuits. Conventionally in 2D circuits, this requires thicker metal layers to propagate power and signals over greater distances. The disclosed mechanisms enable a finer granulation of devices across and among active layers of a 3DIC, enabling shorter wire lengths and thinner metal layers.

The signaling bandwidth of wires is based on a product of the wire resistance and the wire capacitance. For example, halving the length of a wire halves the resistance and halves the capacitance, increasing the wire's bandwidth capacity by a factor of four.

The disclosed mechanisms enable the thinning of metal layers in a 3DIC without loss of overall wire routing density in the 3DIC, thereby reducing a number of metal layers needed to service a particular amount of circuits. The reduction in the number of metal layers leads to a commensurate reduction in the number of needed oxide layers, a reduction in the thickness of the oxide layers, and a reduction in a length and cross-section of through-silicon vias (TSV), improving the overall thermal conductivity of the 3DIC without loss of wire routing density or bandwidth.

The disclosed mechanisms may be utilized with memory circuits, by granulating the memory arrays into smaller blocks and distributing the blocks across multiple active layers in manners that enable the utilization of shorter, thinner metal routes. More generally, the disclosed mechanisms enable functional blocks conventionally comprised by a die to be disaggregated and distributed across different metal layers in a manner that enables denser, thinner metal layers.

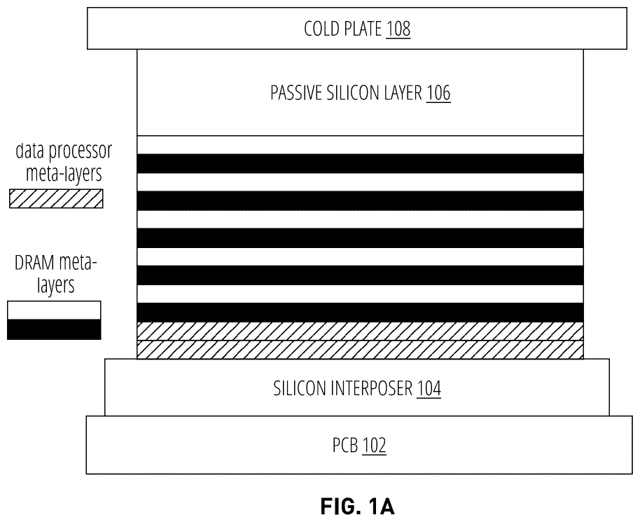

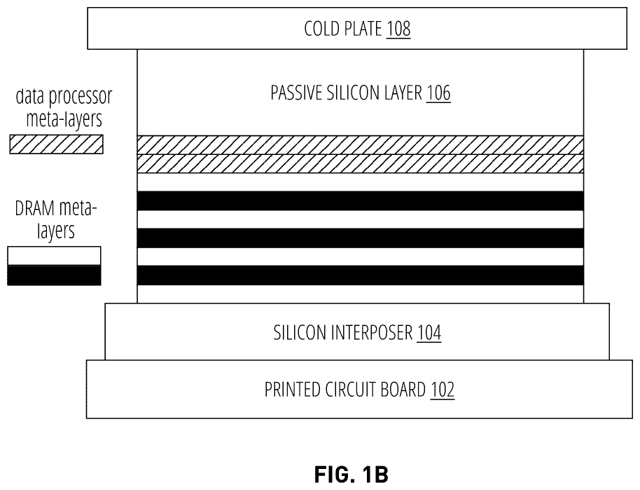

FIG. 1A and FIG. 1B depict 3DIC structures comprising a data processor and a dynamic random access memory (DRAM). The 3DIC comprises multiple meta-layers (layers comprising multiple sub-layers). The 3DIC may be mounted on a printed circuit board 102 with electrical connections to the printed circuit board 102 made through a silicon interposer 104.

In each of the active (die) layers, the dielectric (e.g., silicon dioxide) layers have a high thermal impedance relative to active silicon or metal layers.

Heat generated by the 3DIC during operation may dissipate through a passive silicon layer 106 to a cold plate 108 or other heat sink. For example, in a conventional 3DIC the thickness of the silicon interposer 104 may be set to about 100 um and the thickness of the passive silicon layer 106 (which may be material other than silicon in some 3DIC implementations) may be configured to set the overall 3DIC thickness on the order of 700-760 um.

Using FIG. 1A and FIG. 1B for reference, and unless otherwise indicated, “thickness” refers the extent of a material (metal, silicon, oxide) in the ‘vertical’ dimension between the silicon interposer 104 and the cold plate 108 or other heat sink device.

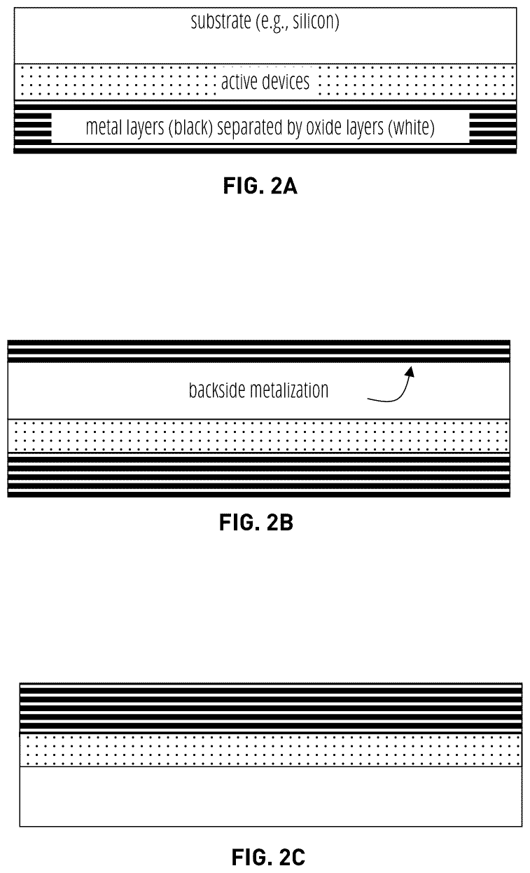

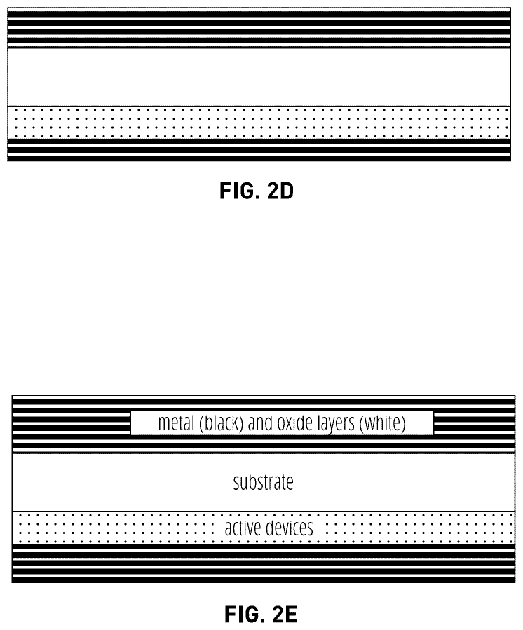

FIG. 2A-FIG. 2E depict various possible configurations of the sublayers in the 3DIC meta-layers relative to the passive silicon layer 106 (‘above’ as in FIG. 1A and FIG. 1B) and the silicon interposer 104 (‘below’ as in FIG. 1A and FIG. 1B). Heat is generated in the active device layers and flows toward the cold plate 108.

In a conventional 3DIC of this type, a thickness of the metal and oxide layers in the DRAM may for example be between 1 um and 10 um. A thickness of the active device DRAM layers may be less than 1 um.

In these structures the oxide layers have a lower thermal conductivity than the other types of layers. For example, oxide may comprise a thermal conductivity of about 0.25 W/m-K (watts per meter-Kelvin) while metal (e.g., copper) and silicon comprise thermal conductivity of about 401 W/m-K and 139 W/m-K, respectively. The DRAM in a conventional 3DIC may for example comprise from 5 to 7 metal layers, each with corresponding oxide layers for insulation. The oxide layers may account for a very high percentage (e.g., >90%) of the overall thermal impedance in the 3DIC.

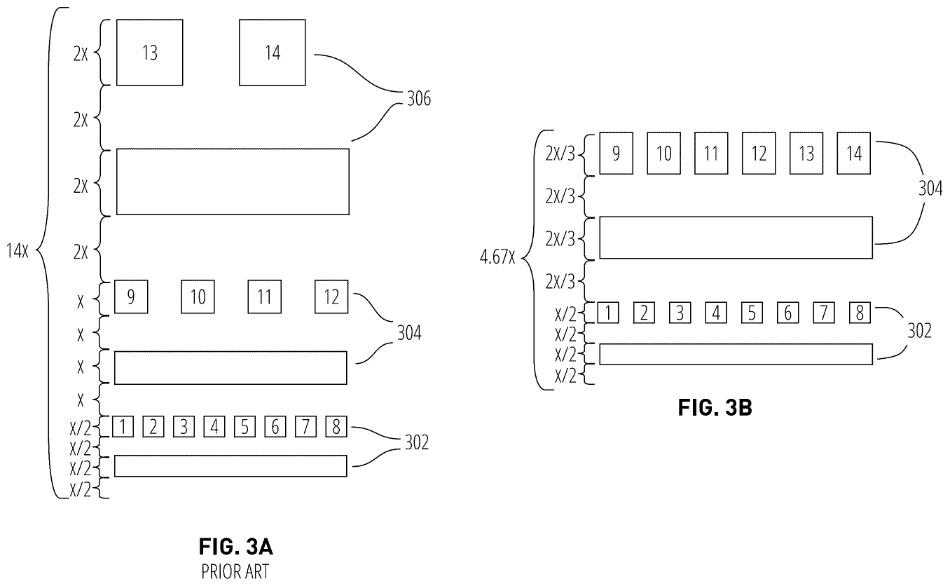

FIG. 3A and FIG. 3B depict an example of a thermal improvement of a 3DIC structure. In practice, unlike the idealized depictions in FIG. 1A and FIG. 1B, the metal stacks in a conventional 3DIC structure comprise a progressive increase in layer thickness and metal geometry. This is utilized so that adequate signaling bandwidth, and sufficiently low latency, may be achieved over long planer (within a layer) distances.

FIG. 3A depicts a 3DIC DRAM structure comprising six metal layers of differing width. The metal layers are depicted with relative thicknesses commonly found in conventional designs. The 3DIC structure comprises two lower metal layers 302 each with thickness x/2, two middle metal layers 304 each with thickness x, and two upper metal layers 306 (e.g., power and ground layers) each with thickness 2x. By way of example, x may be 100 nm for conventional state-of-the-art fabrication processes.

FIG. 3B depicts a 3DIC DRAM structure formed by applying the disclosed fabrication mechanisms. The middle two metal layers 304 are scaled down by a factor of 2x/3 and the number of metal layers is reduced by ⅓. For example, the metal layers 302 may each formed with thickness x/2 and the power metal layer and the ground metal layer each formed with thickness 2x/3. Equivalently, the metal layers 302 may each formed with thickness t and the power metal layer and the ground metal layer each formed with thickness 4t/3.

This yields the same overall (3D) metal routing density in each direction and reduces the thickness of the metal and dielectric layers by 4.67/14-0.33. The overall stack height of the 3DIC DRAM structure is reduced by ⅔. This lowers the thermal impedance by 67%, resulting in a ˜3× higher effective thermal conductivity.

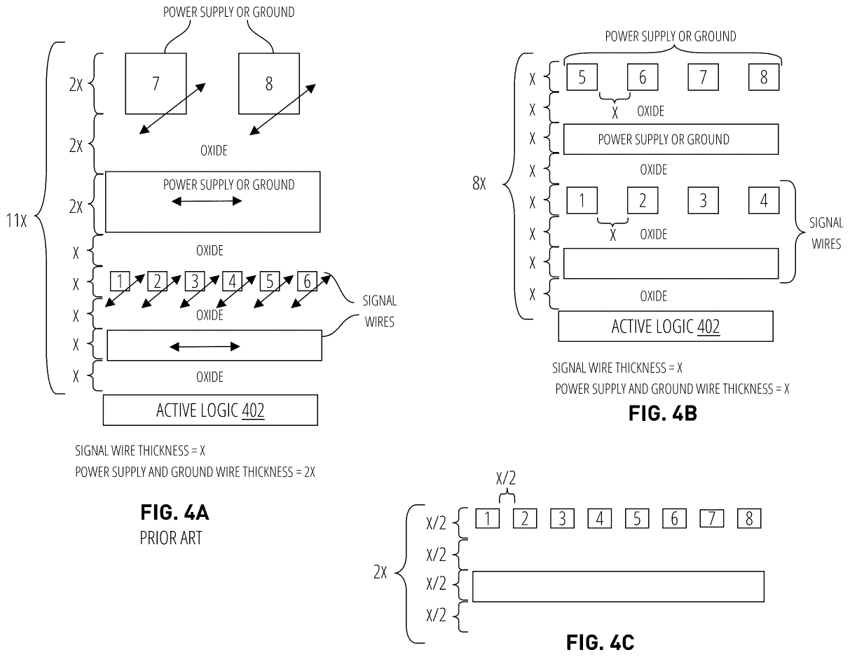

FIG. 4A is a simplistic version of a conventional 3DIC structure comprising four metal layers and an active logic 402 layer. The numbered boxes depict metal tracks running into and out of the screen. The solid bars depict metal layers comprising tracks running left and right.

FIG. 4B depicts normalization of wire thickness across metal layers and reduction of oxide thickness between power/ground layers by 50%. The normalized layer structure maintains the same overall (3D) metal routing density as in FIG. 4A.

The structure in FIG. 4C comprises a reduced number of higher resolution metal layers (thinner wire geometries spaced closer together). This maintains the overall routing density while decreasing the overall oxide thickness by using fewer metal layers that are thinner. The 3DIC structure in FIG. 4C may have 75% lower thermal impedance than the one depicted in FIG. 4B.

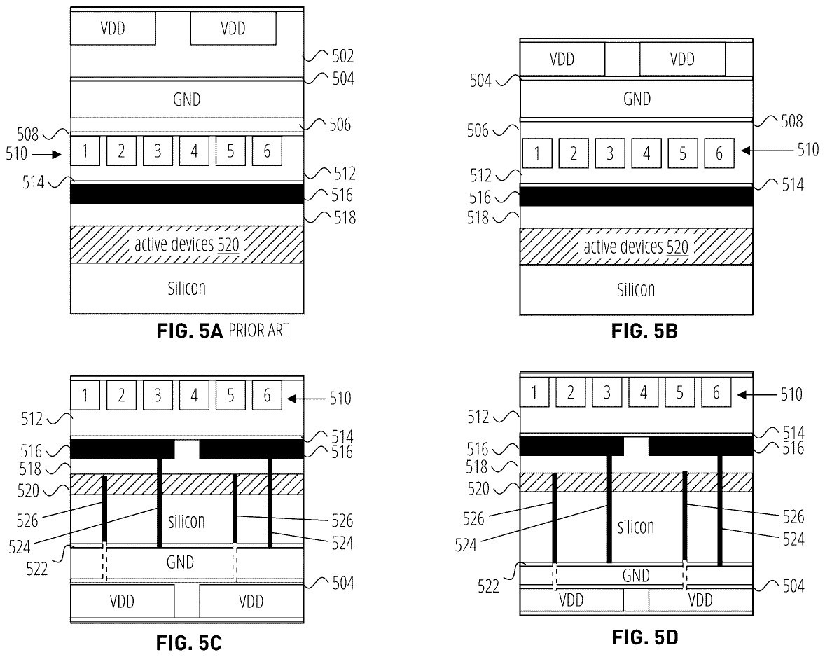

FIG. 5A-FIG. 5D depict a progression that reduces dielectric layers in a 3DIC structure and thereby improves thermal conductivity.

FIG. 5A depicts a conventional 3DIC structure. The 3DIC structure comprises, from top to bottom, a power supply metal layer (VDD), an oxide layer 502, a silicon nitride layer 504, a ground metal layer (GND), an oxide layer 506, a silicon nitride layer 508, a signaling metal layer 510, an oxide layer 512, a silicon nitride layer 514, a metal layer 516 (e.g., GND or VDD), an oxide layer 518, an active device layer 520, and a silicon substrate.

FIG. 5B depicts removal of an oxide layer 502 (e.g., SiO₂) between a ground metal layer (GND) and a power supply metal layer VDD. The GND and VDD layers may be the uppermost metal layers closest to the heat sink, e.g., layers M3 and M4. A silicon nitride layer 504 (Si₃N₄) layer is retained, which may be ˜10× thinner than the oxide layer 502 and comprise ˜2× higher thermal conductivity, yielding a 20× lower thermal resistivity at this portion of the 3DIC, with an added benefit of higher decoupling capacitance between the power supply and ground. The thick oxide layer 502 between the power net and ground metal routing layers may be removed in this manner on condition that high-speed signals are not routed using these layers.

In the structure of FIG. 5B the relationship between planar routing density and the vertical routing density (TSV pitch) determines the optimum distribution of logic block in the active layers. The TSV pitch may be reduced to distances of 1 um or less to enable the necessary connectivity between devices, power, and ground. The spread and distribution of logic gates is constrained by the planar (intralayer) routing density greatly exceeding the vertical (via) routing density.

FIG. 5C depicts a 3DIC in which a ground metal layer and a power supply metal layer are moved to the “backside” of the silicon substrate. The thick oxide layer 506 above the signaling metal layer (e.g., M2) is removed with only a thin (e.g., 50-100 nm) silicon nitride layer 522 configured between the power/ground metal layers and the silicon substrate. Through-silicon vias 524 are configured to electrically couple the metal layer 516 to the backside ground layer (GND). Through-silicon vias 526 are also configured to couple the backside power layer (VDD) to logic in the active device layer 520. The metal track density in the power and ground layers may be greatly increased. With these modifications, thermal conductivity of the 3DIC structure is further improved while also lessening routing congestion between power delivery and data movement metals.

FIG. 5D depicts thinner metal (e.g. ½ the thickness vs the same layers in front-side power delivery) utilized in the backside ground metal and power supply layers as a result of the reduced routing congestion achieved in the 3DIC structure of FIG. 5C. In one embodiment, the signaling metal layer 510, metal layer 516, and backside ground and power metal layers may all be configured with a same thickness (e.g., as per FIG. 4B). No signal routes are configured into the backside metal layers, which are restricted to power and ground routing nets. Via geometries may be reduced as well. Because the layers are thinner, the distance that the vias travel vertically is decreased, and the via cross section may be reduced without loss of bandwidth, thereby reducing the pad sizes on the ends of the vias.

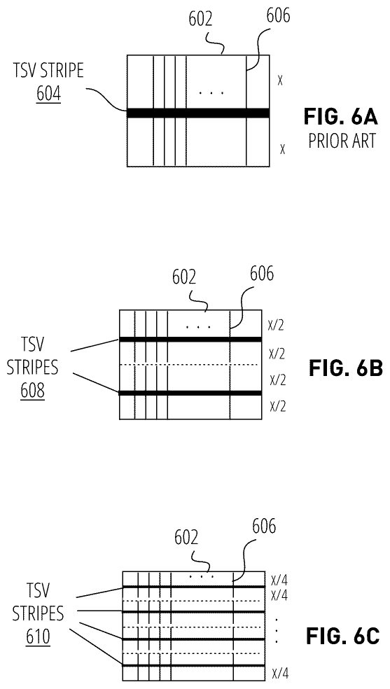

FIG. 6A-FIG. 6C depict configurations of through-silicon via stripes in a metal routing layer for a machine memory array.

FIG. 6A is a simplified depiction of a metal routing layer 602 for a conventional high bandwidth memory (HBM) 3DIC device comprising dimensions of, for example, about 10 mm by 10 mm. A stripe of through-silicon vias 604 is configured to span horizontally (in the depicted orientation of the layer) at a midline of the metal layer 602. Routing metal traces 606 fan out vertically from the through-silicon vias 604, with a maximum length of x and an effective bandwidth capacity of f.

FIG. 6B depicts an embodiment of a metal routing layer for a machine memory array in which a first stripe of through-silicon vias 608 is configured at a distance x/2 from an edge (parallel to the TSV stripe 608) of the metal layer 602 and a second stripe of through-silicon vias 608 is configured at a distance x from the first. The cross-sectional geometry of the through-silicon vias 608 may also be reduced by a factor of ½ (50%). Routing metal traces 606 fan out vertically from the through-silicon vias 608, with a maximum length of x/2 and an effective bandwidth capacity of 4f. A width of the trace 606 may be reduced by ½ (50%), increasing the impedance of the traces 606, while retaining an effective bandwidth capacity of ˜f. The metal layer 602 and oxide layers on either side of it may be reduced in height by a factor of ½ (50%). The cross-sectional geometry of the through-silicon vias 608 may also be reduced by a factor of ½ (50%).

FIG. 6C depicts an embodiment of a metal routing layer for a machine memory array in which a first stripe of through-silicon vias 610 is configured at a distance x/4 from a (horizontal) edge of the metal layer 602 and additional stripes of through-silicon vias 610 are configured at each additional interval x/2 from the first, until the opposite edge of the metal layer 602 is reached. Routing metal traces 606 fan out vertically from the through-silicon vias 608, with a maximum length of x/4 and an effective bandwidth capacity of 16f. A width of the trace 606 may be reduced by a factor of ¼ (75%), increasing the impedance of the traces 606, while retaining an effective bandwidth capacity of ˜f. The cross-sectional geometry of the through-silicon vias 610 may also be reduced by a factor of ¼ (75%). The metal layer 602 and oxide layers on either side of it may be reduced in height by a factor of ¼ (75%).

### LISTING OF DRAWING ELEMENTS

102 printed circuit board
104 silicon interposer
106 passive silicon layer
108 cold plate
302 metal layer
304 metal layer
306 metal layer
402 active logic
502 oxide layer
504 silicon nitride layer
506 oxide layer
508 silicon nitride layer
510 signaling metal layer
512 oxide layer
514 silicon nitride layer
516 metal layer
518 oxide layer
520 active device layer
522 silicon nitride layer
524 through-silicon vias
526 through-silicon vias
602 metal layer
604 through-silicon vias
606 trace
608 through-silicon vias
610 through-silicon vias

Various functional operations described herein may be implemented in logic that is referred to using a noun or noun phrase reflecting said operation or function. For example, an association operation may be carried out by an “associator” or “correlator”. Likewise, switching may be carried out by a “switch”, selection by a “selector”, and so on. “Logic” refers to machine memory circuits and non-transitory machine readable media configured with machine-executable instructions (software and firmware), and/or circuitry (hardware) which by way of its material and/or material-energy configuration comprises control and/or procedural signals, and/or settings and values (such as resistance, impedance, capacitance, inductance, current/voltage ratings, etc.), that may be applied to influence the operation of a device. Magnetic media, electronic circuits, electrical and optical memory, and firmware are examples of logic. Logic specifically excludes pure signals or software per se (however does not exclude non-transitory machine memories comprising software and thereby forming statutory configurations of matter). Logic symbols in the drawings should be understood to have their ordinary interpretation in the art in terms of functionality and various structures that may be utilized for their implementation, unless otherwise indicated.

Within this disclosure, different entities (which may variously be referred to as “units,” “circuits,” other components, etc.) may be described or claimed as “configured” to perform one or more tasks or operations. This formulation-[entity] configured to [perform one or more tasks]—is used herein to refer to structure (i.e., something physical, such as an electronic circuit). More specifically, this formulation is used to indicate that this structure is arranged to perform the one or more tasks during operation. A structure can be said to be “configured to” perform some task even if the structure is not currently being operated. A “credit distribution circuit configured to distribute credits to a plurality of processor cores” is intended to cover, for example, an integrated circuit that has circuitry that performs this function during operation, even if the integrated circuit in question is not currently being used (e.g., a power supply is not connected to it). Thus, an entity described or recited as “configured to” perform some task refers to something physical, such as a device, circuit, memory storing program instructions executable to implement the task, etc. This phrase is not used herein to refer to something intangible.

The term “configured to” is not intended to mean “configurable to.” An unprogrammed FPGA, for example, would not be considered to be “configured to” perform some specific function, although it may be “configurable to” perform that function after programming.

Reciting in the appended claims that a structure is “configured to” perform one or more tasks is expressly intended not to invoke 35 U.S.C. § 112 (f) for that claim element. Accordingly, claims in this application that do not otherwise include the “means for” [performing a function] construct should not be interpreted under 35 U.S.C § 112 (f).

As used herein, the term “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

As used herein, the phrase “in response to” describes one or more factors that trigger an effect. This phrase does not foreclose the possibility that additional factors may affect or otherwise trigger the effect. That is, an effect may be solely in response to those factors, or may be in response to the specified factors as well as other, unspecified factors. Consider the phrase “perform A in response to B.” This phrase specifies that B is a factor that triggers the performance of A. This phrase does not foreclose that performing A may also be in response to some other factor, such as C. This phrase is also intended to cover an embodiment in which A is performed solely in response to B.

As used herein, the terms “first,” “second,” etc. are used as labels for nouns that they precede, and do not imply any type of ordering (e.g., spatial, temporal, logical, etc.), unless stated otherwise. For example, in a register file having eight registers, the terms “first register” and “second register” can be used to refer to any two of the eight registers, and not, for example, just logical registers 0 and 1.

When used in the claims, the term “or” is used as an inclusive or and not as an exclusive or. For example, the phrase “at least one of x, y, or z” means any one of x, y, and z, as well as any combination thereof.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

Although the terms “step” and/or “block” may be used herein to connote different elements of methods employed, the terms should not be interpreted as implying any particular order among or between various steps herein disclosed unless and except when the order of individual steps is explicitly described.

Having thus described illustrative embodiments in detail, it will be apparent that modifications and variations are possible without departing from the scope of the disclosure as claimed. The scope of inventive subject matter is not limited to the depicted embodiments but is rather set forth in the following Claims.

What is claimed is:

1. A three-dimensional integrated circuit (3DIC) comprising:
a data processor comprising a plurality of first metal layers; and
a dynamic random access memory (DRAM) comprising a plurality of second metal layers, wherein:
a distance from a midline of the second metal layers to each edge of the second metal layers is D, and each of the second metal layers comprises a pair of via stripes each positioned at a distance D/2 from each of the edges.

2. The 3DIC of claim 1, further comprising:
a power metal layer and a ground metal layer; and
wherein the second metal layers are each formed with thickness t and the power metal layer and the ground metal layer are each formed with thickness 4t/3.

3. The 3DIC of claim 2, wherein the second metal layers are separated from one another by oxide layers each formed with thickness t.

4. The 3DIC of claim 1, further comprising:
a power metal layer and a ground metal layer; and
wherein the second metal layers are each formed with thickness t and the power metal layer and the ground metal layer are each formed with thickness t.

5. The 3DIC of claim 4, wherein the second metal layers are separated from one another by oxide layers each formed with thickness t.

6. A three-dimensional integrated circuit (3DIC) comprising:
a data processor comprising a plurality of first metal layers; and
a dynamic random access memory (DRAM) comprising a plurality of second metal layers, wherein:
a distance from a midline of the second metal layers to each edge of the second metal layers is D, and each of the second metal layers comprises four via stripes each positioned at a distance D/4 from one another.

7. The 3DIC of claim 6, further comprising:
a power metal layer and a ground metal layer; and
wherein the second metal layers are each formed with thickness t and the power metal layer and the ground metal layer are also each formed with thickness t.

8. The 3DIC of claim 7, wherein the power metal layer and the ground metal layer are backside layers.

9. The 3DIC of claim 8, wherein the power metal layer and the ground metal layer are separated from one another only by a silicon nitride layer.
